(19) United States
(12) Patent Application Publication
(10) Pub. No.: US 2015/0236664 A1
(43) Pub. Date: Aug. 20, 2015

(54) SOUND ENHANCEMENT FOR TELEVISION SPEAKERS

(71) Applicant: Lloyd Trammell, Thousand Oaks, CA (US)

(72) Inventor: Lloyd Trammell, Thousand Oaks, CA (US)

(73) Assignee: Max Sound Corporation, La Jolla, CA (US)

(21) Appl. No.: 14/185,843

(22) Filed: Feb. 20, 2014

(51) Int. Cl. H03G 5/16; H04R 5/04; H04R 3/00

(52) U.S. Cl. CPC H03G 5/16; H04R 3/00; H04R 5/04

(57) ABSTRACT

A process and system for enhancing and customizing sound includes receiving an input audio sound and enhancing the voice audio input in two or more harmonic and dynamic ranges by re-synthesizing the audio into a full range PCM wave. A tone adjusting circuit is provided which includes a first section for adjusting a low frequency tone, a second section for adjusting a mid frequency tone, a third section for adjusting a high frequency tone and mixing the audio outputs processed by the first, second and third sections to produce an output audio sound. The enhancement includes the parallel processing the input audio via a low pass filter with dynamic offset, an envelope controlled bandpass filter, a high pass filter, adding an amount of dynamic synthesized sub bass to the audio and combining the four treated audio signals in a summing mixer with the original audio. The low frequency tone has a frequency of 100 Hz and a bandwidth of 0.5. The mid frequency tone has a frequency of 2500 Hz and an adjustable bandwidth and the high frequency tone has a frequency of 10 KHz and an adjustable bandwidth.

### CROSS-REFERENCE TO RELATED PATENT APPLICATIONS

Embodiments of the present invention relate to U.S. Provisional Application Ser. No. 61/767,197, filed Feb. 20, 2013, entitled “TELEVISION”, the contents of which are incorporated by reference herein and which is a basis for a claim of priority.

### BACKGROUND OF THE INVENTION

Conventional audio input into a television is provided by an external device, such as a DVD player or cable/broadcast. When the audio is input into this device there is typically an input level control that controls the gain or volume of the entire unit. The audio path typically ends at a transducers or speakers for user listening or preamp output for a separate external amplification system.

The speakers in this type of system are typically small with very little efficiency and frequency range. These speakers are most times very low cost systems with low cost components, which affect the quality of sound produced by the television.

What is needed is a sound enhancement system and process that addresses the above deficiencies of the conventional systems.

### SUMMARY OF THE PREFERRED EMBODIMENT(S)

The inventive processor for Television speakers is built into the television, providing it with more harmonic and dynamic range than without the process. The stereo audio Input is provided by an external device, such as a DVD player or cable/broadcast. When the audio is input into this device there is typically an input level control that controls the gain or volume of the entire unit. According to an embodiment the audio path is as shown in FIG. 1 with the audio ending at the transducers or speakers for user listening. Using the Max Sound process, the television speakers have a more full and dynamic sound than without.

The settings for these parameters will vary by television brand and size. Each different model will have a “custom” set of parameter settings for that model. These settings are fixed and not user adjustable. A particular and specific speaker would need to be measured, or analyzed, for its response characteristics to get an accurate representation of that speaker before the Max Sound process. After this analysis, the same or duplicate speaker analyzing is done on the output after the complete Max Sound process in the same speaker. This allows the manufacturer to adjust the settings for optimizing the response characteristics to a “target” or more desirable sound. Both of these measurement procedures are performed by the manufacturer. It is noted that the inventive WAT module is a user setting that is adjustable to allow the user to fine tune the sound to their preferences.

The inventive process and system for enhancing and customizing Television speaker sound includes receiving an input audio sound and enhancing the voice audio input in two or more harmonic and dynamic ranges by re-synthesizing the audio into a full range PCM wave. A tone adjusting circuit is provided which includes a first section for adjusting a low frequency tone, a second section for adjusting a mid frequency tone, a third section for adjusting a high frequency tone and mixing the audio outputs processed by the first, second and third sections to produce an enhanced output audio sound.

The inventive audio enhancement process includes the parallel processing the input audio via a low pass filter with dynamic offset, an envelope controlled bandpass filter, a high pass filter, adding an amount of dynamic synthesized sub bass to the audio and combining the four treated audio signals in a summing mixer with the original audio. The low frequency tone has a frequency of 100 Hz and a bandwidth of 0.5. The mid frequency tone has a frequency of 2500 Hz and an adjustable bandwidth and the high frequency tone has a frequency of 10 KHz and an adjustable bandwidth.

A particular and specific powered speaker would need to be measured, or analyzed, for its response characteristics to get an accurate representation of that speaker before the Max Sound process. After this analysis, the same or duplicate speaker analysis is performed on the output after the complete Max Sound process in the same speaker. This allows the manufacturer to adjust the settings for optimizing the response characteristics to a “target, or more desirable sound. Both of these measurements are performed by the manufacturer. As noted herein, the inventive WAT process is a user setting that is adjustable to allow the user to fine tune the sound to their preference.

### BRIEF DESCRIPTION OF THE DRAWINGS

FIG. 1 is a block diagram of an embodiment of the audio process of the present invention.

FIG. 2 shows a typical use/implementation of the inventive Max Sound Processor according to an embodiment of the present invention.

FIG. 3 shows a flow chart of the inventive Wave Adjustment Tool according to an embodiment of the present invention.

### DETAILED DESCRIPTION OF THE PREFERRED EMBODIMENT(S)

The inventive process of the present application includes two stages, a Max Sound module and a tone adjustment module (WAT). Implementing the inventive process into any speakers, results in an increase in the harmonic and dynamic range of these speakers. Since the process is dynamic in its control method, it also eliminates many of the phase anomalies that occur in normal unprocessed speakers. This will make them more efficient and much clearer sounding with the same hardware.

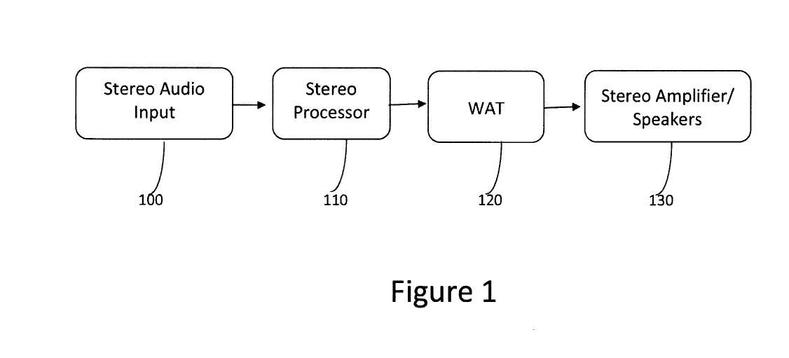

In one embodiment, the television speakers in which the inventive process is implemented are powered and have a processor for processing the inventive processes built into them. In one embodiment, the audio input is provided by an external device, such as a CD or MP3 player. When the audio is input into this device there is typically an input level control that controls the gain or volume of the entire unit. The audio path is, e.g., as shown in FIG. 1 with the audio ending at the transducers or speakers for user listening.

Following the processing of the audio input by the Max Sound processor module, the processed sound is fed to the inventive Wave Adjustment Tool (WAT), which includes controls available for the user to adjust the tonality of the audio to his/her liking For example, the controls are LOW, MID, and HIGH. These controls can be located on one side of the speaker unit. The tone control is an improvement over the conventional tone adjustments in part because it is based on a dynamic approach that monitors the content of the received audio and adjusts itself to compensate for any changes in both a positive and negative direction. The end result is very pleasing and a more natural sound of the content being played. The WAT is not limited only three bands. More dynamic bands may be added as desired by programming them into the process and assigning the frequency, band width, and amount of dynamic change to be allowed per band. In this case it is a digital process, but it may be hardware (analog) if desired in any output format (mono, stereo, 5.1, 7, 1, etc.)

The details of the present invention will now be further explained by reference to the drawings.

Referring to FIG. 1, stereo audio input 100 is audio form a powered speaker. The powered speaker is measured, or analyzed, for its response characteristics to get an accurate representation of that speaker prior to subjecting its output to the Max Sound process (not shown). The same speaker analysis is performed on the output after the complete Max Sound process in the same speaker (not shown). This allows the manufacturer to adjust the settings for optimizing the response characteristics to a “target, or more desirable sound. Both of these measurements are performed by the manufacturer.

Audio input 100 is fed to the inventive Max Sound Processor 110 for processing. The processing results in an increase in the harmonic and dynamic range of these speakers. Since the process is dynamic in its control method, it also eliminates many of the phase anomalies that occur in normal unprocessed speakers. This will make them more efficient and much clearer sounding with the same hardware. Sound processed by the inventive Max Sound Processor 110 is fed to the inventive WAT (Wave Adjustment Tool) 120, which includes controls available for the user to adjust the tonality of the audio to user's liking, and is then outputted to the speakers 130.

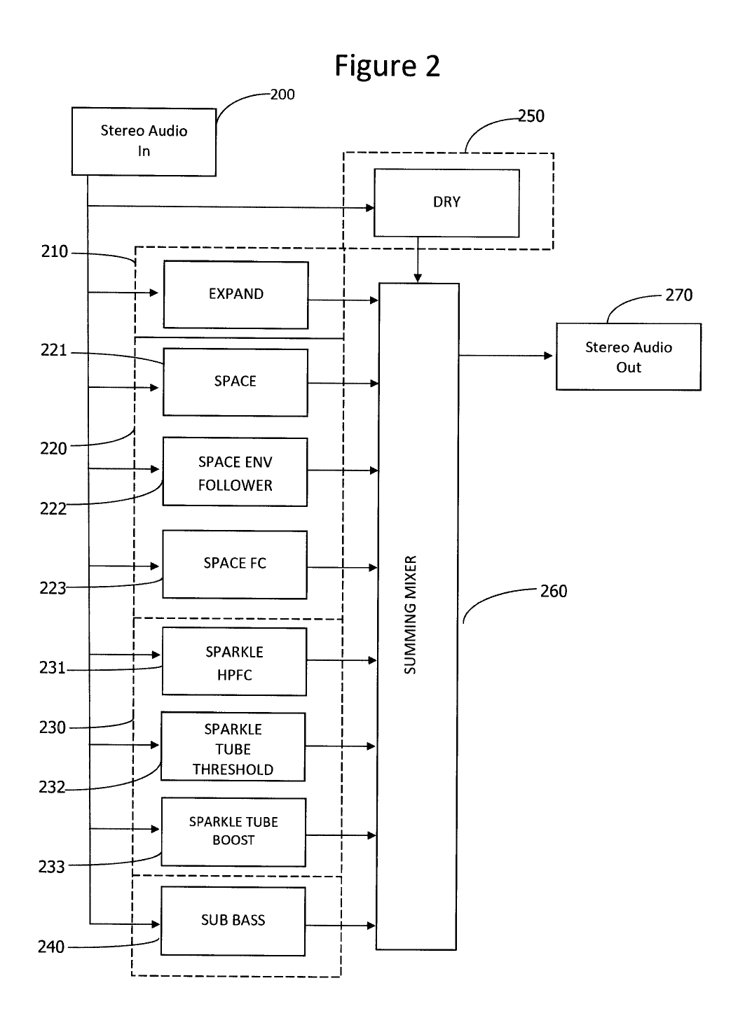

Further details of the inventive Max Sound Processor will now be described with reference to FIG. 2. Stereo Audio input 200 is processed, in parallel, by several modules as follows. EXPAND 210 is preferably a 4 pole digital low pass filter with an envelope follower for dynamic offset (fixed envelope follower). This allows the output of the filter to be dynamically controlled so that the output level is equal to whatever the input is to this filter section. For example, if the level at the input is −6 dB, then the output will match that. Moreover, whenever there is a change at the input, the same change will occur at the output regardless of either positive or negative amounts. The frequency for this filter is, e.g., 20 to 20 k hertz, which corresponds to a full range. In one embodiment, the purpose of EXPAND 310 is to “warm up” or provide a fuller sound as waveform 100 passes through it. The original audio 200 passes through, and is added to the effected sound for its output. As the input amount varies, so does the phase of this section. This applies to all filters used in this software application. Preferably all filters are of the Butterworth type.

Next, we discuss SPACE 220. SPACE 220 refers to the block of three modules identified by reference numerals 221, 222 and 223. The first module SPACE 221—which follows EXPAND 210 envelope follower, sets the final level of this module. This is the effected signal only, without the original. SPACE ENV FOLLOWER 222 tracks the input amount and forces the output level of this section to match. SPACE FC 223 sets the center frequency of the 4 pole digital high pass filter used in this section. This filter also changes phase as does EXPAND 210.

SPACE blocks 220 are followed by the SPARKLE 230 blocks. Like SPACE 220, there are several components to SPARKLE. SPARKLE HPFC 231 is a 2 pole high pass filter with a preboost which sets the lower frequency limit of this filter. Anything above this setting passes through the filter while anything below is discarded or stopped from passing. SPARKLE TUBE THRESH 232 sets the lower level at which the tube simulator begins working. As the input increases, so does the amount of the tube sound. The tube sound adds harmonics, compression and a slight bit of distortion to the input audio 200. This amount increases slightly as the input level increases. SPARKLE TUBE BOOST 233 sets the final level of the output of this module. This is the effected signal only, without the original.

Next, the SUB BASS 240 module is discussed. This module takes the input signal and uses a low pass filter to set the upper frequency limit to about 100 Hz. An octave divider occurs in the software that changes the input signal to lower by an octave (12 semi tones) and output to the only control in the interface, which is the level or the final amount. This is the effected signal only, without the original.

Outputs from the above modules 210 to 240 are directed into SUMMING MIXER 250 which combines the audio. The levels going into the summing mixer 250 are controlled by the various outputs of the modules listed above. As they all combine with the original signal 200 fed through the DRY 260 module there is interaction in phase, time and frequencies that occur dynamically. These changes all combine to create a very pleasing audio experience for the listener in the form of “enhanced” audio content. For example, a change in a single module can have a great affect on what happens in relation to the other modules final sound or the final harmonic output of the entire software application.

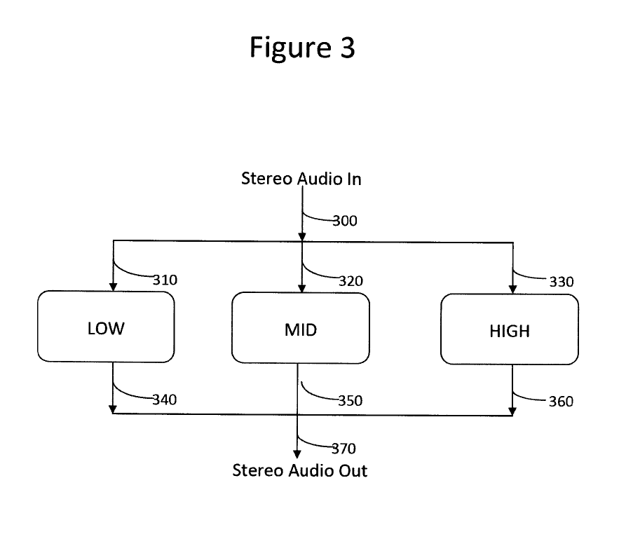

Continuing with reference to FIG. 3, output from the Max Sound Processor of FIG. 2 is received for further processing by the Wave Adjustment Tool of the present invention for tone adjustment. Input audio 300 is processed in parallel by the three sections of the WAT tone adjusting circuit, which include the LOW 310, MID 320 and HIGH 330 sections. The audio processed by the three sections (shown by reference numerals 340, 350 and 360 in FIG. 2) are then mixed to form output audio 370.

According to one embodiment of the present invention the LOW section has a frequency of 100 Hz and a 0.5 bandwidth; MID has a frequency of 2500 Hz with an adjustable bandwidth; and HIGH has a 10 kHz frequency and an adjustable bandwidth.

For MID, the center frequency is dynamically moved in both positive and negative amounts according to the input level of this bandpass filter. Preferably, the range is from 1.7 kHz on the low end to 4.5 kHz on the upper end with 2.5 kHz as the center or nominal setting. As the input level goes positive or negative, so the bandwidth will change. For a negative change the bandwidth will increase, for e.g., to a .5, while a positive change will decrease, for e.g., to a .1. This provides a larger frequency change for negative and a smaller, more precise change for positive level amounts in the filtered audio content.

In reference to the HIGH tone control section the center frequency is fixed, e.g., at 10 kHz, but the bandwidth changes dynamically in positive amounts as the input level changes. For negative amounts the bandwidth stays at, e.g., .5, when the level decreases the bandwidth goes only to a max bandwidth of e.g., .3.

What is claimed is:

1. A process and system for enhancing and customizing sound comprising:
Receiving an input audio sound;
Enhancing the voice audio input in two or more harmonic and dynamic ranges by re-synthesizing the audio into a full range PCM wave;
A tone adjusting circuit, comprising;
A first section for adjusting a low frequency tone;
A second section for adjusting a mid frequency tone;
A third section for adjusting a high frequency tone;
Mixing the audio outputs processed by the first, second and third sections to produce an output audio sound.

2. The process of claim 1, wherein the enhancement includes the parallel processing the input audio as follows:
A module that is a low pass filter with dynamic offset;
An envelope controlled bandpass filter;
A high pass filter;
Adding an amount of dynamic synthesized sub bass to the audio;
Combining the four treated audio signals in a summing mixer with the original audio.

3. The process of claim 2, wherein the low frequency tone has a frequency of 100 Hz and a bandwidth of 0.5.

4. The process of claim 2, wherein the mid frequency tone has a frequency of 2500 Hz and an adjustable bandwidth.

5. The process of claim 2, wherein the high frequency tone has a frequency of 10 KHz and an adjustable bandwidth.

6. The process of claim 2, wherein the input audio sound is processed for a determination of its response characteristics prior to being processed by the enhancing step.
